(19) United States
(12) Patent Application Publication
(10) Pub. No.: US 2006/0275940 A1
(43) Pub. Date: Dec. 7, 2006

(54) METHOD FOR CONTROLLING WELL CAPACITY OF A PHOTODIODE

(76) Inventors: Ming-Chun Su, Hsin-Chu Hsien (TW); Chien-Chang Huang, Hsin-Chu Hsien (TW); Chih-Cheng Hsieh, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/380,660

(22) Filed: Apr. 28, 2006

(30) Foreign Application Priority Data
Jun. 7, 2005 (TW) 094118787

(51) Int. Cl. H01L 21/00

(52) U.S. Cl. 438/57

(57) ABSTRACT

A method for controlling well capacity of a photodiode includes providing a reference voltage, which is greater than a voltage of ground, to a gate of a transfer transistor while exposing the photodiode whose one end is connected to ground, so as to control the well capacity of the photodiode.

### BACKGROUND OF THE INVENTION

1. Field of the Invention

The present invention relates to a method for controlling an active pixel, and more particularly, to a method for controlling well capacity of a photodiode.

2. Description of the Prior Art

Please refer to FIG. 1, which is a circuit diagram of an active pixel 8 according to the prior art. The active pixel 8 comprises a pinned photodiode 10, a transfer transistor 12, a reset transistor 14, a source-follower transistor 16, and a row-selector transistor 18. The pinned photodiode 10 receives light; the transfer transistor 12 controls transfer of photoelectric charge of the pinned photodiode 10; the reset transistor 14 resets the pinned photodiode 10; the potential of a source of the source-follower transistor 16 changes with the charge at a gate of the source-follower transistor 16; and the row-selector transistor 18 controls read-out of light signals or reset signals.

The operation of the active pixel 8 is as follows. The active pixel 8 performs a reset process, turning on the reset transistor 14 and the transfer transistor 12. A high voltage, such as a maximum operating voltage Vdd, is provided to gates of the reset transistor 14 and the transfer transistor 12 for resetting the pinned photodiode 10. Next, the active pixel 8 is exposed for capturing images. During the exposure process, the reset transistor 14 and the transfer transistor 12 are turned off. A low voltage, such as zero volts, is provided to the gate of the transfer transistor 12 to turn off the transfer transistor 12. At the same time, the pinned photodiode 10 receives light and stores charge in its well. Please refer to FIG. 2, which shows charge storage at a node P and a node R of FIG. 1. The node P represents the charge storage of the pinned photodiode 10, and the node R represents the charge storage at a source of the reset transistor 14.

Next, a reset signal is read. Please refer to FIG. 3, which is an illustration of reading the reset signal. The charge at the node R is transferred through the source-follower transistor 16 and the row-selector transistor 18. At this time, the transfer transistor 12 and the reset transistor 14 are turned off while the source-follower transistor 16 and the row-selector transistor 18 are turned on. After the reset signal is read, a light signal is read. Please refer to FIG. 4, which is an illustration of reading the light signal. The transfer transistor 12 is turned on to transfer the charge stored in the pinned photodiode 10. Then, the light signal is read via the source-follower transistor 16 and the row-selector transistor 18, completing image capture.

The active pixel 8 of the prior art has two disadvantages. One is a blooming phenomenon, and the other is image lag. These are detailed as follows.

Please refer to FIG. 5 and FIG. 6. FIG. 5 shows the transfer transistor 12 and the pinned photodiode 10 in an intense light condition. FIG. 6 shows photoelectric charge flowing over the well of the pinned photodiode 10 of FIG. 5. Zero volts are provided to the gate of the transfer transistor 12 to turn off the transfer transistor 12, exposing the pinned photodiode 10. If the pinned photodiode 10 is exposed to intense light, the pinned photodiode 10 might receive too much photoelectric charge, and results in photoelectric charge flowing over the well of the pinned photodiode 10. In other words, the well capacity of the pinned photodiode 10 is full of photoelectric charge, and cannot store more photoelectric charge. At this time, since the transfer transistor 12 is turned off, there is no path to pass more photoelectric charge. Therefore, photoelectric charge flows to adjacent pixels, resulting in the blooming phenomenon.

Additionally, during a semiconductor process, it is very difficult to control the well capacity of the pinned photodiode 10. If the well capacity is not properly controlled, image lag results, as shown in FIG. 7, which shows image lag at the nodes P and R of FIG. 1. Since the charge at the node P of FIG. 7 cannot be transferred completely, some charge remains at the node P, and thereby image lag occurs. What the prior art usually does for preventing image lag is to control the well capacity of the pinned photodiode 10 or to control a charge storage at the source of the reset transistor 14 via a semiconductor process. However, it is difficult to control the semiconductor process and the cost is high.

### SUMMARY OF THE INVENTION

The claimed invention provides an image device comprising a photodiode, a first transistor, a reference voltage control unit, a second transistor, a third transistor, and a fourth transistor. The photodiode receives light. The first transistor has a source coupled to the photodiode, and controls transfer of photoelectric charge of the photodiode. The reference voltage control unit is coupled to a gate of the first transistor. The reference voltage control unit receives a plurality of control signals, and provides a reference voltage to the gate of the first transistor according to the received control signals for controlling well capacity of the photodiode. The second transistor has a source coupled to an output of the first transistor, and a drain coupled to a voltage source. The second transistor resets the photodiode. The third transistor has a drain coupled to the voltage source, and a gate coupled to the source of the second transistor. The fourth transistor has a drain coupled to a source of the third transistor, and a source coupled to a pixel line. The fourth transistor controls read-out of signals.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of an active pixel according to the prior art.

FIG. 2 shows charge storage at a node P and a node R of FIG. 1.

FIG. 3 is an illustration of the active pixel of FIG. 1 reading the reset signal.

FIG. 4 is an illustration of the active pixel of FIG. 1 reading the light signal.

FIG. 5 shows the transfer transistor and the pinned photodiode of FIG. 1 in an intense light condition.

FIG. 6 shows photoelectric charge flowing over the well of the pinned photodiode of FIG. 5.

FIG. 7 shows image lag at the node P and R of FIG. 1.

FIG. 8 is a diagram of a transfer transistor and a pinned photodiode.

FIG. 9 shows the well capacity of the pinned photodiode of FIG. 8.

FIG. 10 is a diagram of a device to control the well capacity of the pinned photodiode according to the present invention.

FIG. 11 to FIG. 13 show the charge stored in the pinned photodiode when different reference voltages are provided.

FIG. 14 to FIG. 16 respectively show the photoelectric charge transfer of the pinned photodiode of FIG. 11 to FIG. 13.

FIG. 17 is a flowchart of controlling the charge stored in the pinned photodiode according to the present invention.

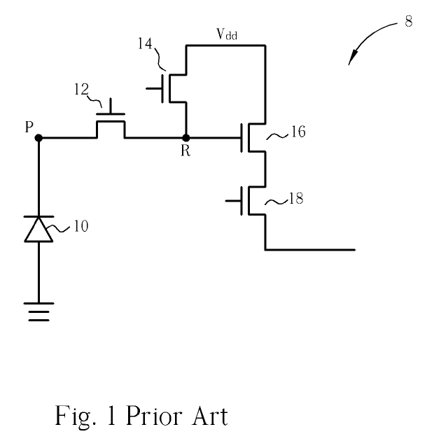

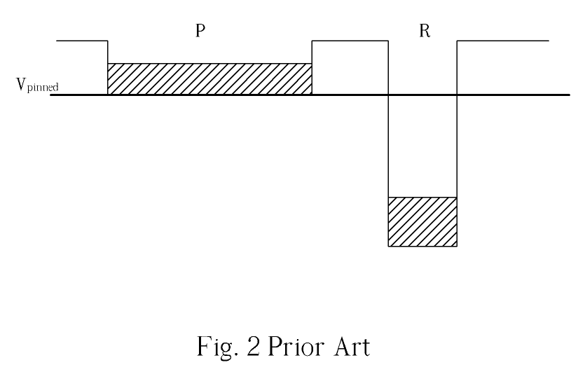

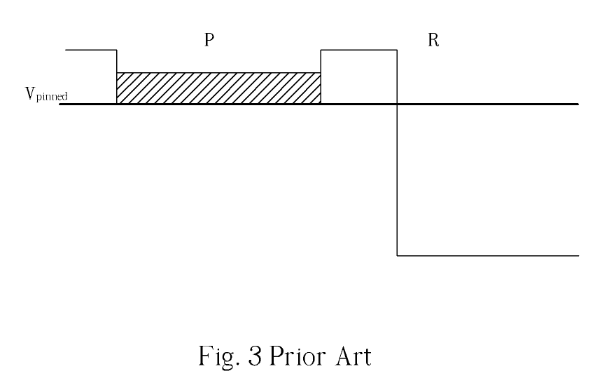

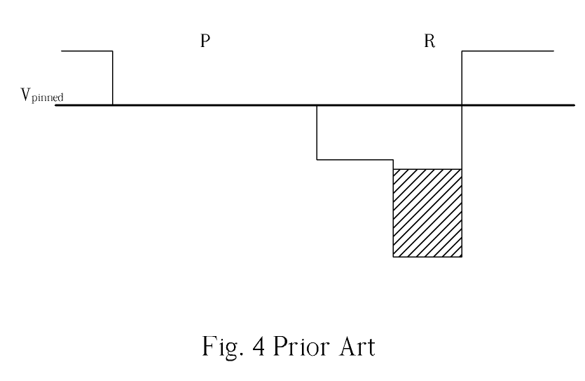

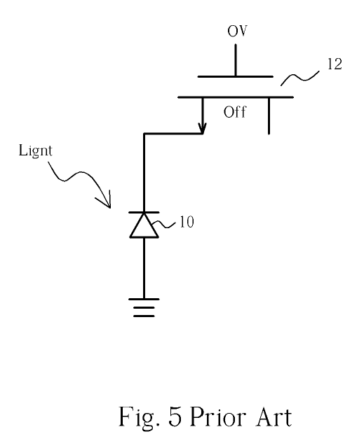

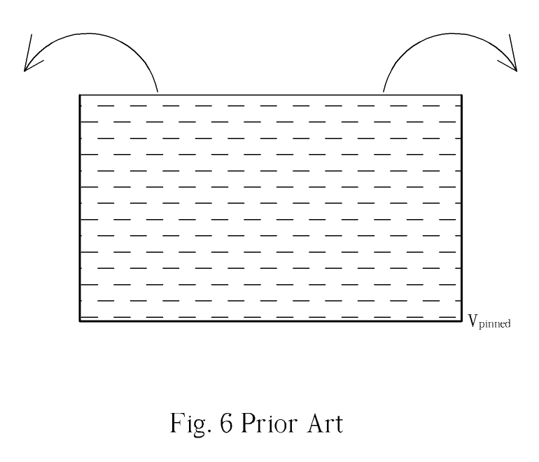

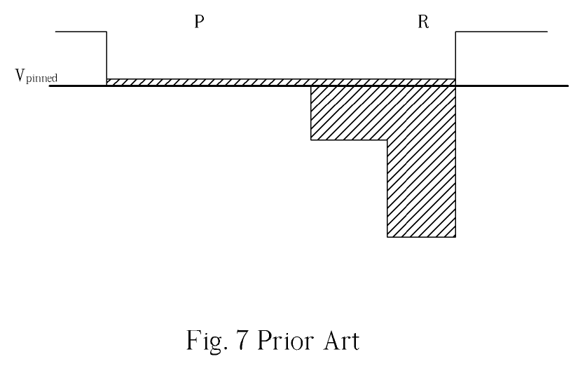

### DETAILED DESCRIPTION

The present invention provides a method to control the well capacity of the pinned photodiode 10 so as to solve the image lag and the blooming phenomenon problems in the prior art.

Firstly, the concept of the present invention is introduced as follows. If the charge of the pinned photodiode 10 cannot be completely transferred since image lag will occur. Therefore, the present invention reduces the charge stored in the pinned photodiode 10 so as to prevent image lag. Additionally, the blooming phenomenon results from receiving too much photoelectric charge flowing to adjacent pixels. Controlling the charge stored in the pinned photodiode 10 can prevent the blooming phenomenon.

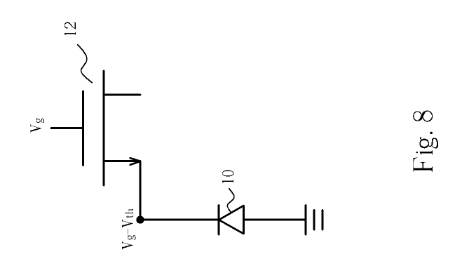

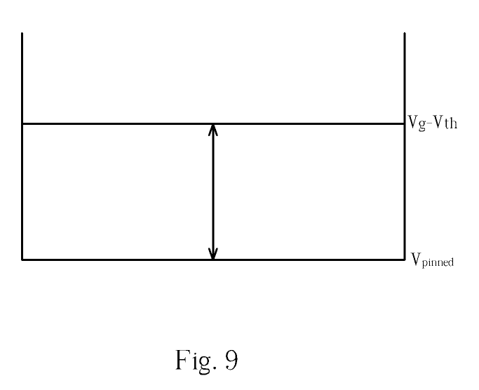

Please refer to FIG. 8, which is a diagram of the transfer transistor 12 and the pinned photodiode 10. When a voltage V_{g} is provided at the gate of the transfer transistor 12, since the transfer transistor 12 has a threshold voltage Vₜₕ, a voltage at the source of the transistor 12 is (V_{g}−Vₜₕ), wherein Vₜₕ includes a body effect. Please refer to FIG. 9, which shows the well capacity of the pinned photodiode 10 of FIG. 8. In FIG. 9, voltage values approaching the bottom become larger. That is, the voltage value of V_{pinned} is larger than the voltage value of (V_{g}−Vₜₕ). From FIG. 9, the well capacity of the pinned photodiode 10 is the range between V_{pinned} and (V_{g}−Vₜₕ).

The well capacity of the pinned photodiode 10 is dependent on two voltages, V_{pinned} and (V_{g}−Vₜₕ). The pinned voltage V_{pinned} and the threshold voltage Vₜₕ of the pinned photodiode 10 are constant after the semiconductor process is finished. The only way to change the well capacity of the pinned photodiode 10 is to change the voltage V_{g} provided to the gate of the transfer transistor 12. In other words, if the larger voltage V_{g} is provided to the gate of the transfer transistor 12, the well capacity of the pinned photodiode 10 is smaller.

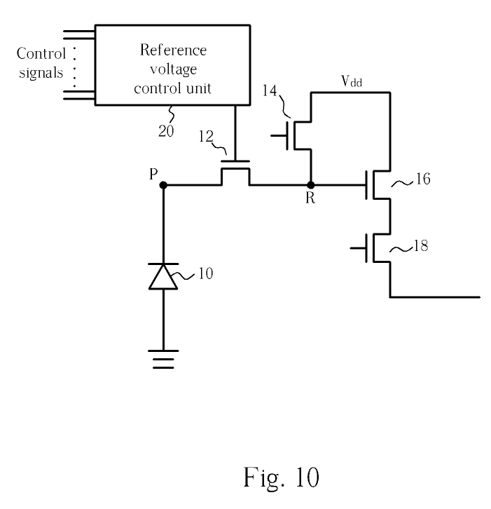

In this way, the present invention controls the voltage provided at the gate of the transfer transistor 12 during the exposure process, so that the well capacity of the pinned photodiode 10 can be controlled. Please refer to FIG. 10, which is a diagram of a device to control the well capacity of the pinned photodiode 10 according to the present invention. The present invention comprises a reference voltage control unit 20. When the image lag or the blooming phenomenon occurs, a plurality of control signals are sent to the reference voltage control unit 20 to adjust a reference voltage provided to the gate of the transfer transistor 12 during the exposure process. Therefore, the well capacity of the pinned photodiode 10 of FIG. 9 can be changed.

In the prior art, zero volts are provided at the gate of the transfer transistor 12 during the exposure process so as to turn off the transfer transistor 12. However, the present invention provides the reference voltage larger than zero volts to the gate of the transfer transistor 12 during the exposure process, and the reference voltage is smaller than a maximum operating voltage.

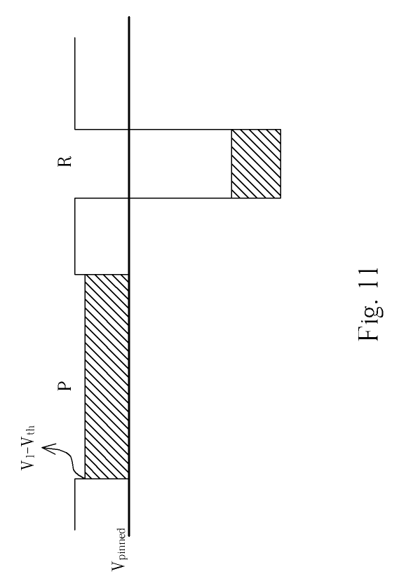

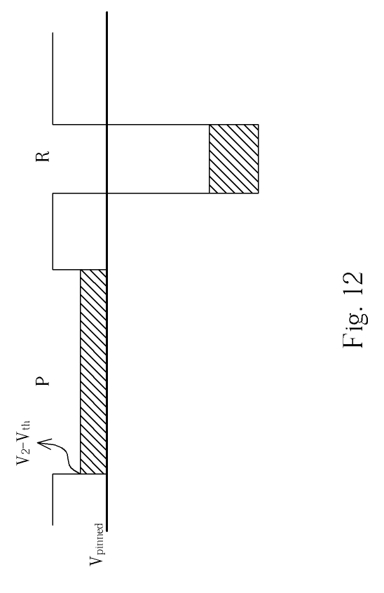

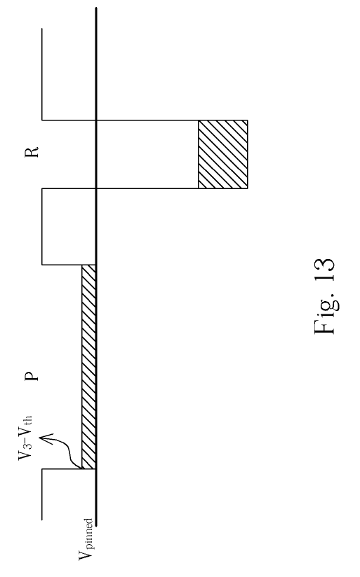

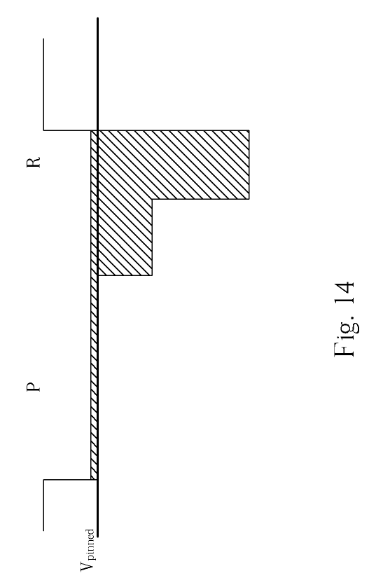

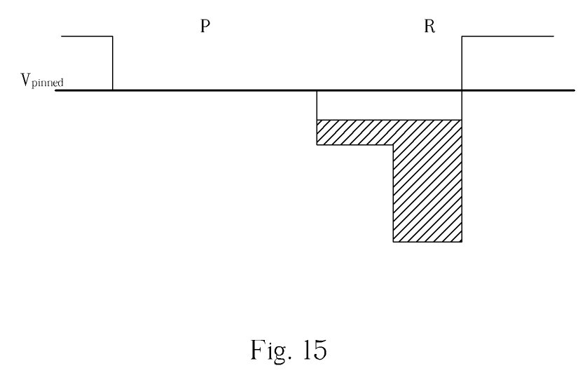

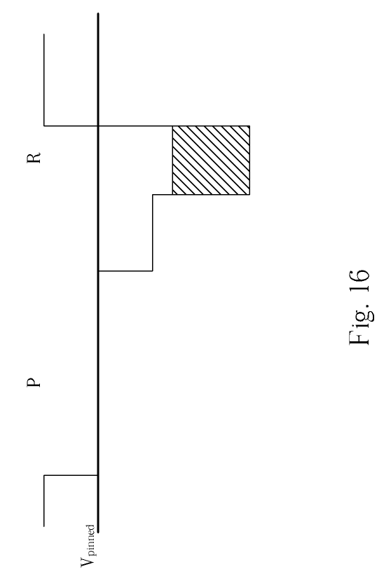

For instance, the reference voltage larger than zero volts is provided to the gate of the transfer transistor 12. Please refer to FIG. 11 to FIG. 13, which show the charge stored in the pinned photodiode 10 when different reference voltages are provided, wherein V₁ is smaller than V₂ while V₂ is smaller than V₃. From FIG. 11 to FIG. 13, the charge stored in the pinned photodiode 10 of FIG. 111 is the largest; the next is FIG. 12; and the smallest is FIG. 13. That is, the larger voltage provided to the gate of the transfer transistor 12, the less charge stored in the pinned photodiode 10. The charge of the pinned photodiode 10 is ready to be transferred after the reset process, the exposure process and reading the reset signal are done. Please to refer to FIG. 14 to FIG. 16, which show the transfer of FIG. 111 to FIG. 13, respectively. If image lag, such as that shown in FIG. 14, occurs, the voltage provided to the gate of the transfer transistor 12 must be increased, such as providing V₃ to prevent image lag. As shown in FIG. 16, the charge of the pinned photodiode 10 is completely transferred.

From the above, the photodiode is not limited to the pinned photodiode 10. Other types of active photodiode can be implemented in the present invention.

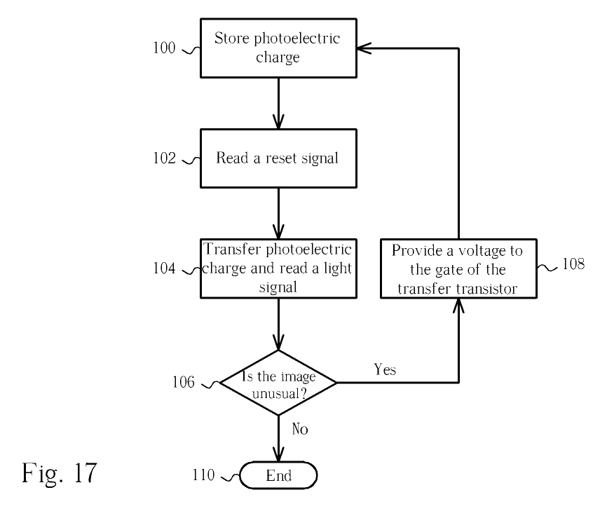

Please refer to FIG. 17, which is a flowchart of controlling the charge stored in the pinned photodiode 10 according to the present invention.

Step 100: The reset process and the exposure process are performed so as to store photoelectric charge in the pinned photodiode 10;

Step 102: A reset signal is read;

Step 104: The photoelectric charge of the pinned photodiode 10 is transferred, and a light signal is read;

Step 106: Detect whether an image has unusual phenomena, such as the blooming phenomenon, image lag, etc. If an unusual phenomenon occurs, step 108 is entered.

Otherwise, step 110 is entered;

Step 108: Control signals are sent to the reference voltage control unit 20. During the exposure process, the reference voltage control unit 20 provides the reference voltage larger than zero volts to the gate of the transfer transistor 12, so that the charge stored in the pinned photodiode 10 can be reduced. Then step 100 is entered;

Step 110: The charge stored in the pinned photodiode 10 is well controlled.

Compared to the prior art, the present invention provides a method for controlling the well capacity of the pinned photodiode. The reference voltage greater than the voltage of ground is provided to the gate of the transfer transistor so as to change the charge stored in the pinned photodiode, and thereby prevent image lag and the blooming phenomenon. After the semiconductor process is finished, the present invention utilizes the reference voltage control unit to change the well capacity of the pinned photodiode. The method of the present invention makes it easier to control the well capacity of the pinned photodiode than the method of the prior art, and the cost is much lower.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image device for controlling photoelectric charge capacity, the image device comprising:
a photodiode for receiving light;
a first transistor having a source coupled to the photodiode, the first transistor controlling transfer of photoelectric charge of the photodiode;
a reference voltage control unit coupled to a gate of the first transistor, the reference voltage control unit receiving a plurality of control signals, and providing a reference voltage to the gate of the first transistor according to the received control signals for controlling well capacity of the photodiode;
a second transistor having a source coupled to an output of the first transistor and a drain coupled to a voltage source, the second transistor resetting the photodiode;
a third transistor having a drain coupled to the voltage source and a gate coupled to the source of the second transistor; and
a fourth transistor having a drain coupled to a source of the third transistor and a source coupled to a pixel line, the fourth transistor controlling read-out of signals.

2. The image device of claim 1, wherein the reference voltage provided to the gate of the first transistor is between zero and a potential of the voltage source.

3. The image device of claim 1, wherein when the reference voltage control unit provides the reference voltage to the gate of the first transistor, the photodiode is exposed so as to control the well capacity of the photodiode.

4. The image device of claim 1, wherein the photodiode is a pinned photodiode.

5. A method for controlling well capacity of a photodiode of an active pixel, the method comprising:
providing a reference voltage greater than a voltage of ground to a gate of a transfer transistor while exposing a photodiode whose one end is coupled to ground for controlling well capacity of the photodiode.

6. The method of claim 5, wherein providing the reference voltage comprises
providing a reference voltage less than a maximum operating voltage.

7. The method of claim 5, wherein exposing the photodiode comprises exposing a pinned photodiode.

8. The method of claim 5, wherein providing the reference voltage to the gate of the transfer transistor comprises a reference voltage control unit receiving a plurality of control signals and providing the reference voltage to the gate of the transfer transistor according to the received control signals.

9. The method of claim 5 further comprising detecting whether an image has unusual phenomena.

10. The method of claim 9, wherein detecting whether the image has unusual phenomena comprises detecting whether image lag occurs in the image.

11. The method of claim 9, wherein detecting whether the image has unusual phenomena comprises detecting whether a blooming phenomenon occurs in the image.
